(19) United States
(12) Patent Application Publication
(10) Pub. No.: US 2013/0188165 A1
(43) Pub. Date: Jul. 25, 2013

(54) LITHOGRAPHY APPARATUS, AND METHOD OF MANUFACTURING ARTICLE

(71) Applicant: CANON KABUSHIKI KAISHA, Tokyo (JP)

(72) Inventors: Shigeki OGAWA, Utsunomiya-shi (JP); Koichi SENTOKU, Kawachi-gun (JP); Hideki INA, Tokyo (JP)

(73) Assignee: CANON KABUSHIKI KAISHA, Tokyo (JP)

(21) Appl. No.: 13/739,196

(22) Filed: Jan. 11, 2013

(30) Foreign Application Priority Data
Jan. 23, 2012 (JP) 2012-011558

(51) Int. Cl. G03F 9/00

(52) U.S. Cl. CPC G03F 9/7003
USPC 355/72; 355/77

(57) ABSTRACT

A lithography apparatus includes: a rotation mechanism configured to rotate a substrate; a first measurement device configured to measure a position of an alignment mark formed on the substrate in a first direction with a first precision; a second measurement device configured to measure a position of an alignment mark formed on the substrate in a second direction with a second precision higher than the first precision; and a controller configured to control the rotation mechanism so that a direction, in which the substrate requires an overlay precision higher than another direction, is aligned with the second direction.

### BACKGROUND OF THE INVENTION

1. Field of the Invention

The present invention relates to a lithography apparatus, and a method of manufacturing an article.

2. Description of the Related Art

The manufacture of LSIs includes a process called cutting lithography or 1D lithography. In this cutting lithography process, lines in a line-and-space pattern already formed on a wafer are cut to have a desired line length, or unwanted lines in this pattern are deleted. The wafer alignment precision required in the cutting lithography process is 8 nm or less for 3σ. However, only the direction in which the line length is determined requires such a high wafer alignment precision, and a wafer alignment precision which prevents adjacent lines from overlapping each other suffices in a direction perpendicular to that in which the line length is determined. In, for example, a 50-nm line-and-space pattern, the variations need only fall within a tolerance of ±20 nm.

Not only this lithography process but also lithography apparatuses such as an exposure apparatus and an electron beam drawing apparatus are required to attain an especially low CoO (Cost of Ownership). However, at present, the requirement for the alignment precision is so strict that an expensive lithography apparatus with high alignment performance must be used for critical processes. Hence, the conventional lithography apparatus guarantees the same wafer alignment performance in both the X- and Y-directions. For this reason, even if the direction in which the line length is determined has changed, the conventional lithography apparatus can cope with this change.

Japanese Patent Laid-Open No. 2009-54737 discloses an alignment optical system which detects, through the same field of view of one detection optical system, a fine alignment mark for measurement in the X-direction and a fine alignment mark for measurement in the Y-direction, that are arranged adjacent to each other, thereby shortening the measurement time. Also, Japanese Patent Laid-Open No. 4-199810 proposes a method in which before a substrate to be exposed is loaded onto a stage, the orientation of the substrate is matched with the exposure direction, and the substrate is then positioned using an alignment pin. As described above, techniques of shortening the wafer alignment time or matching the orientation of the substrate with the drawing direction have been proposed. However, neither an apparatus nor a technique which simultaneously attains both a given alignment performance and a given CoO based on the difference in required alignment precision between different directions has yet come into practical use.

Among various performances of a lithography apparatus which forms a desired circuit pattern on a substrate by exposure to light or by drawing with an electron beam, the CoO has recently become of prime importance. As practical methods of improving the CoO performance, a variety of methods including a reduction in apparatus cost, an increase in number of wafers processed per unit time, a reduction in power consumption or utility usage, and addition of, for example, a function/added value are available, and these methods are applicable to wafer alignment measurement as well.

In a wafer alignment measurement process, precisions required for wafer alignment measurement can be set in both the X- and Y-directions. These precisions required for measurement in the X- and Y-directions may be the same as or different from each other. For example, if the precision required for measurement in the X-direction is higher than that for measurement in the Y-direction, execution of the same wafer alignment measurement process in both directions, as in the conventional technology, often makes it impossible to satisfy given specifications in the direction which requires a higher precision, leading to a decrease in yield. Also, when measurement in the direction which requires a lower precision is performed in accordance with the measurement conditions in the direction which requires a higher precision, the measurement conditions including the measurement count are overdesigned in the direction which the required precision is lower, so measurement time is wasted in the process of the wafer alignment sequence. This may lower the throughput and, in turn, lower the CoO.

### SUMMARY OF THE INVENTION

In view of this, the present invention provides, for example, a lithography apparatus advantageous in terms of satisfaction of a CoO and a required precision.

The present invention provides a lithography apparatus comprising: a rotation mechanism configured to rotate a substrate; a first measurement device configured to measure a position of an alignment mark formed on the substrate in a first direction with a first precision; a second measurement device configured to measure a position of an alignment mark formed on the substrate in a second direction with a second precision higher than the first precision; and a controller configured to control the rotation mechanism so that a direction, in which the substrate requires an overlay precision higher than another direction, is aligned with the second direction.

Further features of the present invention will become apparent from the following description of exemplary embodiments with reference to the attached drawings.

### BRIEF DESCRIPTION OF THE DRAWINGS

FIG. 1A is a view showing the configuration of an electron beam drawing apparatus;

FIGS. 1B and 1C are enlarged views of wafer alignment measurement systems;

FIG. 2 is a schematic view showing the configuration of the electron beam drawing apparatus;

FIG. 3 is a flowchart of wafer alignment measurement by the electron beam drawing apparatus;

FIG. 4 is a view showing the configuration of the conventional lithography apparatus; and

FIG. 5 is a view showing the system configuration of an exposure apparatus which uses a mask.

### DESCRIPTION OF THE EMBODIMENTS

Embodiments of the present invention will be described below with reference to the accompanying drawings.

### First Embodiment

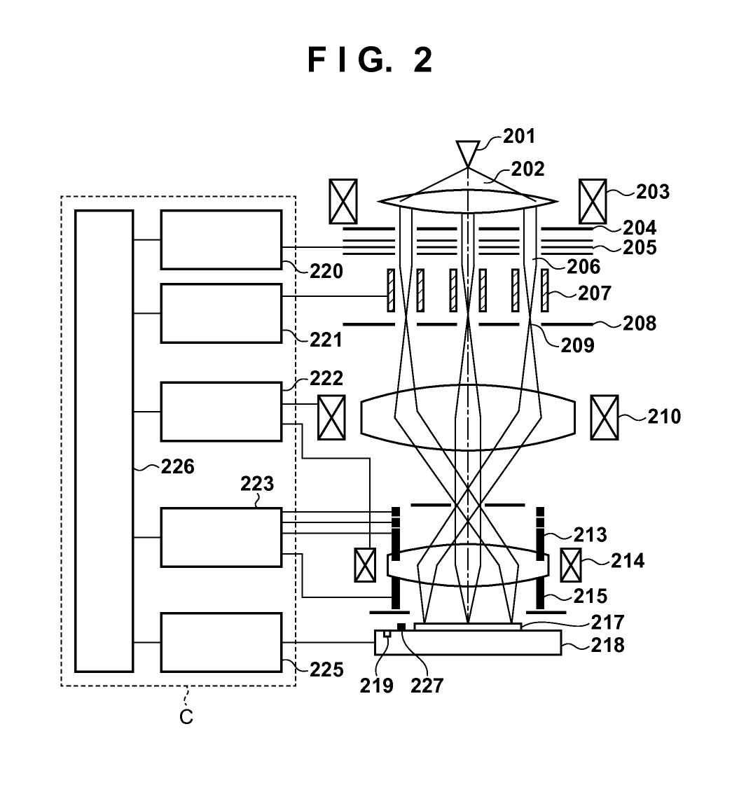

FIG. 2 is a schematic view showing the first embodiment, in which a drawing apparatus which draws a pattern on a substrate with an electron beam is employed as a lithography apparatus. A drawing apparatus which draws a pattern on a substrate with another charged particle beam such as an ion beam in place of an electron beam can also be employed as a lithography apparatus. An electron beam 202 emitted by an electron gun 201 is converted into a plurality of nearly collimated electron beams 206 by a condenser lens 203. The electron beams 206 nearly collimated by the condenser lens 203 are split by an aperture array 204, and form intermediate images 209 of the crossover of the electron gun 201 in the vicinities of blanking apertures 208 by a lens array 205 driven by a focus control circuit 220. The positions of these intermediate images 209 can be changed in the optical axis direction by changing the intensities of individual light beams incident on the lens array 205. Also, upon application of a voltage to a blanking array 207, the intermediate images 209 move perpendicularly to the optical axis, and light beams which bear the pieces of information of the intermediate images 209 are blocked by the blanking apertures 208, thereby allowing ON/OFF control of the individual split electron beams 206.

The intermediate images 209 formed in the vicinities of the blanking apertures 208 are projected onto a wafer 217 on a wafer stage (substrate stage) 218 by an electron optical system including a first electrostatic lens (or electromagnetic lens) 210 and second electrostatic lens (or electromagnetic lens) 214. The electron optical system is driven by a lens control circuit 222 so as to match the rear focal position of the first electrostatic lens 210 with the front focal position of the second electrostatic lens 214. At this time, the plurality of electron beams 206 which form the intermediate images 209, respectively, are collectively deflected and positioned by a main deflector 213 and a sub deflector 215. For example, the deflection width of the main deflector 213 is set wide, while that of the sub deflector 215 is set narrow. Drawing is performed by synchronizing ON/OFF control of the electron beams 206 by an irradiation amount control circuit 221 based on pattern data stored in a CPU 226, and the deflection operations of the main deflector 213 and sub deflector 215 driven by a deflection control circuit 223.

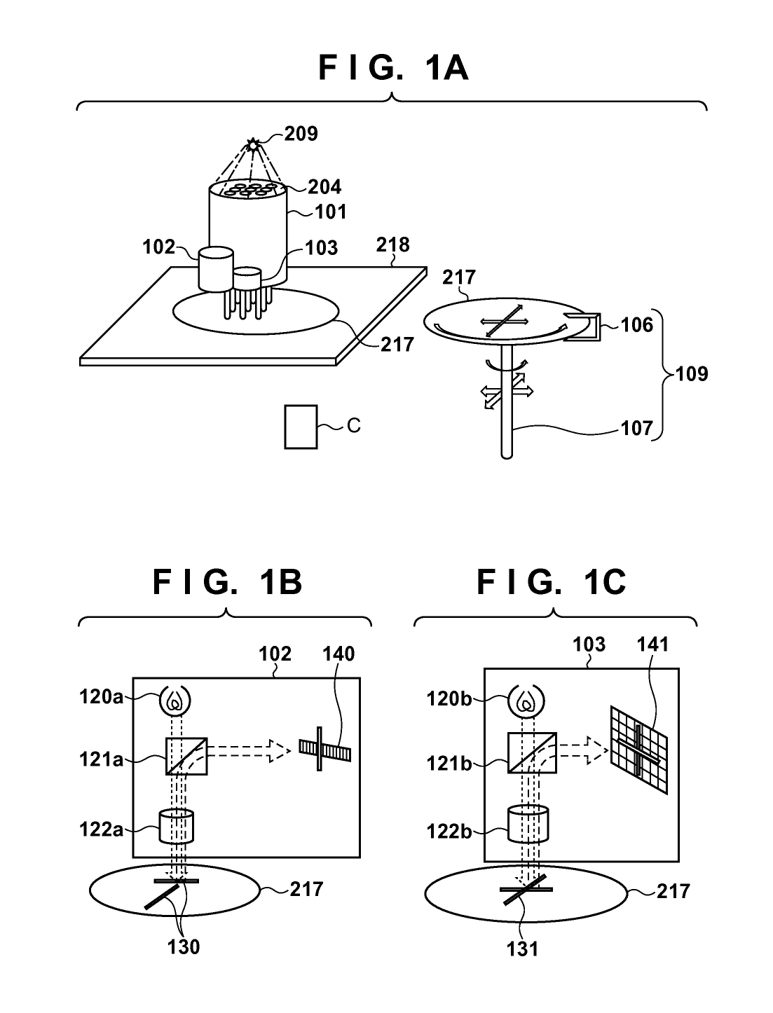

The system configuration of the drawing apparatus according to the first embodiment will be described with reference to FIG. 1A. An electron beam is emitted toward an electron optical system (projection system) 101 using a crossover image formed by the electron gun 201 as a light source, thereby forming a plurality of electron beams 206 by the aperture array 204. Subsequent processes for the electron beams 206 are the same as those described above.

In the first embodiment, in addition to the electron optical system 101 which guides the electron beam onto the wafer 217, a measurement system which measures wafer alignment marks formed on the wafer (substrate) 217 is provided. Also, a first direction and a second direction perpendicular to it are defined in the drawing apparatus. A wafer alignment measurement system includes a wafer alignment measurement system (first measurement device) 103 and wafer alignment measurement system (second measurement device) 102. The wafer alignment measurement system 103 measures, with a first precision (low precision), the position, in the first direction, of an alignment mark 131 formed on the wafer 217. The low-precision wafer alignment measurement system 103 has a measurement precision lower than that of the high-precision wafer alignment measurement system 102 by about an order of magnitude, that is, has a measurement reproducibility of about 30 to 50 nm/3σ. In the first embodiment, the wafer alignment measurement system 103 measures the position of an alignment mark 131 in the second direction with the first precision (low precision) as well. The wafer alignment measurement system 102 measures, with a second precision higher than the first precision, the position, in the second direction, of an alignment mark 130 formed on the wafer 217. The high-precision wafer alignment measurement system 102 has a measurement reproducibility of 8 nm/3σ or less.

The wafer alignment measurement system need not always separately include the high-precision wafer alignment measurement system 102 and low-precision wafer alignment measurement system 103. For example, high- and low-precision wafer alignment measurement operations may be implemented by providing one wafer alignment measurement system with a mechanism which switches the measurement magnification. The roles of the high-precision wafer alignment measurement system 102 and low-precision wafer alignment measurement system 103 are roughly divided as follows.

The wafer 217 is measured using the wafer alignment measurement system 103 which has a wide measurement possible range but low precision first to obtain an approximate amount of shift of the wafer 217. An approximate amount of shift of the wafer 217 is obtained to reliably allow the alignment marks 130 to fall within the measurement range of the wafer alignment measurement system 102 when the wafer 217 is measured using the wafer alignment measurement system 102 which has a narrow measurement possible range but high precision next.

FIGS. 1B and 1C illustrate examples of the configurations of the high-precision wafer alignment measurement system 102 and low-precision wafer alignment measurement system 103, respectively. A light source 120a of the high-precision wafer alignment measurement system 102 may be, for example, a halogen lamp which emits white light, or a HeNe laser which emits monochromatic light with a wavelength to which the resist has no sensitivity. When a light source which emits white light is used, the light wavelength is limited by a light wavelength filter (not shown) as this light contains wavelengths that react with the resist applied on the surface of the wafer 217 in measuring the alignment marks 130 on the wafer 217.

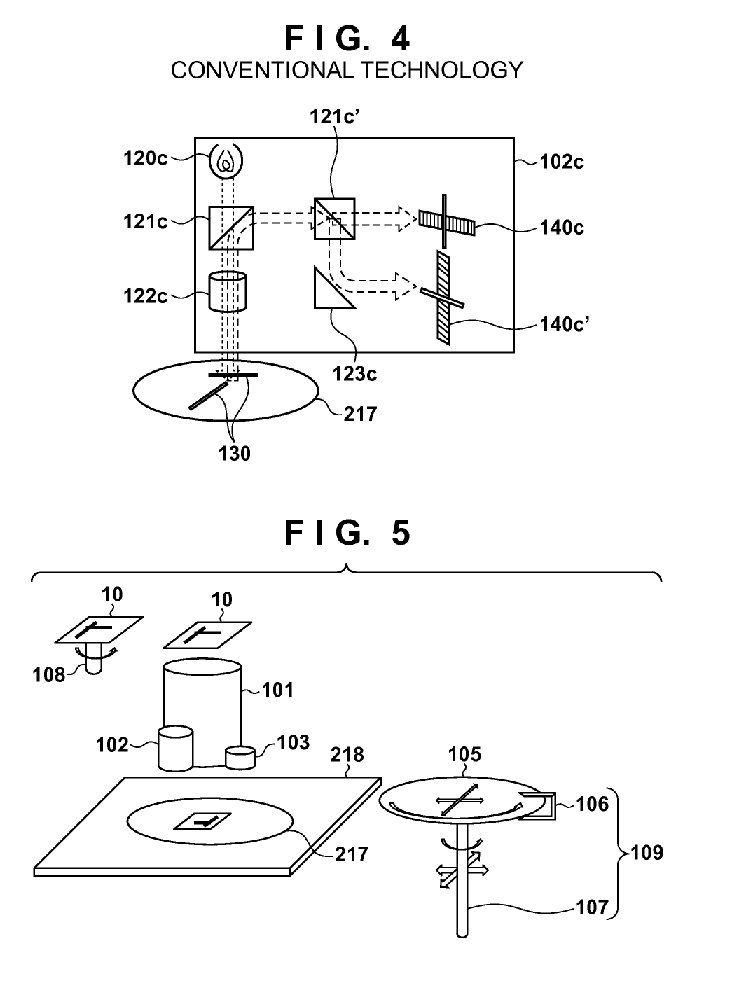

Light emitted by the light source 120a passes through a half mirror 121a, and illuminates the alignment marks 130 on the wafer 217 from an objective lens 122a. An optical system (not shown) is set so that the illuminating light is reflected by the wafer 217, passes through the objective lens 122a, and is then bent by 90° by the half mirror 121a to form an image on a high-resolution sensor 140. In contrast to this, the conventional lithography apparatus includes an alignment measurement system having a configuration, as shown in FIG. 4, because it performs alignment measurement in both the first direction (for example, the X-direction) and the second direction (for example, the Y-direction). To obtain the amount of shift of the wafer 217 so as to draw a pattern on the wafer 217 upon overlay with high precision, the conventional lithography apparatus requires measurement in both the X- and Y-directions. Hence, a conventional high-precision wafer alignment measurement system 102c requires a light source 120c, an optical system, and two sensors 140c and 140c′ for individually measuring two alignment marks 130 in the respective measurement directions. The optical system includes a half mirror 121c, objective lens 122c, half mirror 121c′, and reflecting mirror 123c.

The basic configuration of the low-precision wafer alignment measurement system 103 shown in FIG. 1C is the same as that of the high-precision wafer alignment measurement system 102. However, the wafer alignment measurement system 103 has a low optical magnification, and measures the alignment marks 131 different from the alignment marks 130 measured by the wafer alignment measurement system 102. Also, the wafer alignment measurement system 103 uses a low-resolution sensor 141 to measure the alignment marks 131. Moreover, the wafer alignment measurement system 103 uses the two-dimensional sensor 141 so as to measure the alignment marks 131 in both the X- and Y-directions at once.

The drawing apparatus according to the first embodiment also includes a rotation mechanism 109 which can rotate the wafer 217 about an axis perpendicular to its surface, and adjusts the orientation of the wafer 217 when the wafer 217 is loaded onto the wafer stage 218, in response to a command from a stage control circuit 225. In the first embodiment, the rotation mechanism 109 serves as a prealignment mechanism which performs prealignment of the wafer 217 before the wafer 217 is loaded onto the wafer stage 218. The rotation mechanism 109 includes a wafer driver 107 capable of rotation driving and shift driving in the X- and Y-directions as the wafer 217 is mounted on it, and a wafer detector 106 which detects the position of the wafer 217 in the rotation direction and the X- and Y-directions, as shown in FIG. 1A.

The operation of the mechanism which adjusts the orientation of the wafer 217 will briefly be described. First, the wafer 217 is loaded onto the wafer driver 107. The wafer detector 106 detects the notch of the wafer 217 while the wafer driver 107 rotates the wafer 217. The wafer driver 107 rotates and shifts the wafer 217 to allow the wafer detector 106 to accurately detect the notch of the wafer 217, thereby obtaining the position of the wafer 217. Note that the wafer detector 106 need not always detect the notch of the wafer 217, and may detect, for example, an arbitrary mark on the wafer 217. The wafer driver 107 is also equipped with a function of rotating the wafer 217 through an arbitrary rotation angle with reference to the position at which the notch of the wafer 217 is detected.

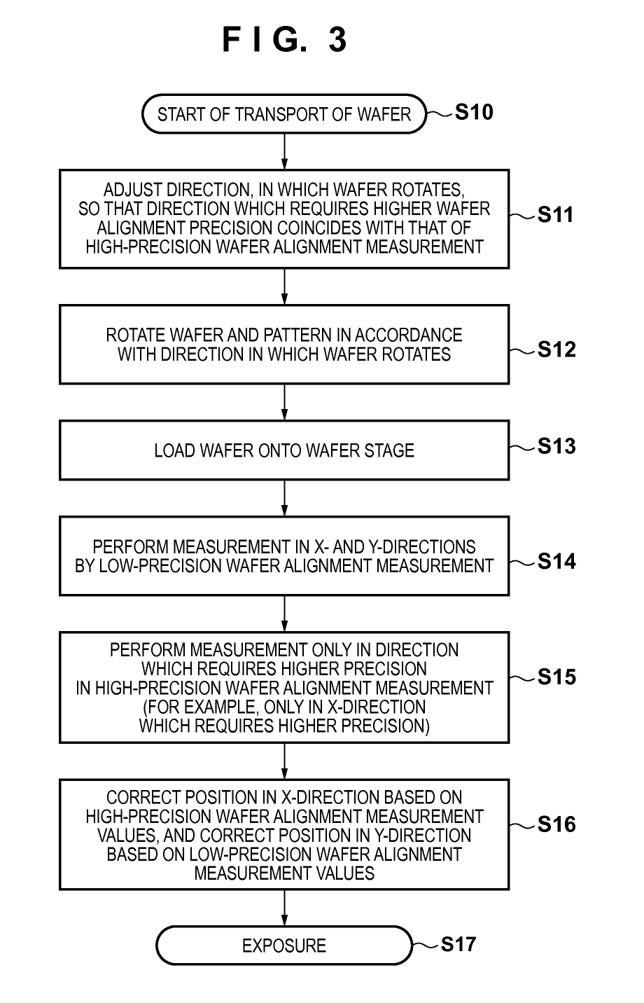

The sequence of a wafer alignment process in such a drawing apparatus will be described with reference to a flowchart shown in FIG. 3. First, in step S10, a wafer 217 is transported into the drawing apparatus from outside. In transporting the wafer 217 into the drawing apparatus, a resist required to form a pattern by exposure has already been applied onto the wafer 217. An underlying circuit pattern and alignment marks have also already been formed on the wafer 217.

In step S11, the orientation and position, in the X- and Y-directions, of the wafer 217 transported into the drawing apparatus are adjusted by the wafer driver 107 in order to determine the direction in which the wafer 217 is loaded onto the wafer stage 218 first, as described with reference to FIG. 1A. At this time, the orientation of the wafer 217 is adjusted so that the direction in which the wafer 217 is to be aligned with high precision coincides with the measurement direction of the high-precision wafer alignment measurement system 102.

Upon detection of the notch of the wafer 217 by the wafer detector 106, if the orientation of the wafer 217 coincides with the measurement direction of the high-precision wafer alignment measurement system 102, a controller C sets the wafer 217 on the wafer stage 218 in this orientation in step S13. If the orientation of the wafer 217 differs from the measurement direction of the wafer alignment measurement system 102, the controller C rotates the wafer 217 with reference to the position, at which the notch is detected, so that the orientation of the wafer 217 coincides with the measurement direction of the wafer alignment measurement system 102 (step S12), and sets the wafer 217 on the wafer stage 218 (step S13).

In step S14, wafer alignment measurement in both the X- and Y-directions is performed for the wafer 217, which is set and held on the wafer stage 218, using the alignment marks 131 by the low-precision wafer alignment measurement system 103 first. The controller C aligns the wafer 217 using the wafer alignment measurement values obtained in step S14. This reliably allows the alignment marks 130 to fall within the measurement range of the high-precision wafer alignment measurement system 102.

In step S15, high-precision wafer alignment measurement is performed for the wafer 217 using the alignment marks 130 by the high-precision wafer alignment measurement system 102. In step S16, the controller C corrects the position of the wafer 217 in the X-direction based on the high-precision wafer alignment measurement values, and corrects the position of the wafer 217 in the Y-direction based on the low-precision wafer alignment measurement values. Although the position in the X-direction is adjusted with high precision in the first embodiment, the position in the Y-direction may be adjusted with high precision.

Lastly, in step S17, the controller C overlays a drawing pattern on the pattern on the aligned wafer 217. At this time, the drawing pattern must also be rotated in accordance with the direction in which the wafer 217 rotates. The controller C rotates the drawing pattern in accordance with the direction in which the wafer 217 rotates, and then draws a pattern with an electron beam in step S17. Although the rotation mechanism 109 serves as a prealignment mechanism in the first embodiment, it may serve as a rotation mechanism which rotates the wafer stage 218.

### Second Embodiment

The second embodiment of the present invention, in which an exposure apparatus which projects a pattern formed on a mask onto a substrate to expose the substrate is employed as a lithography apparatus, will be described with reference to FIG. 5. FIG. 5 is a view showing the system configuration of the exposure apparatus according to the second embodiment. The basic system configuration in the second embodiment is the same as that described in the first embodiment. A wafer 217 is loaded onto a wafer stage 218, alignment marks on the wafer 217 are measured in both the X- and Y-directions by a low-precision wafer alignment measurement system 103, and alignment measurement in only one direction is performed by a high-precision wafer alignment measurement system 102. The wafer 217 is aligned using alignment data obtained by the wafer alignment measurement systems 103 and 102.

The wafer 217 is driven by a wafer driver 107, and the position of the wafer 217 is detected by a wafer detector 106 which detects the notch of the wafer 217. In the second embodiment, a projection system 101 which projects a pattern onto the wafer 217 serves as a projection optical system which projects light. A pattern to be projected onto the wafer 217 is formed on a mask (also called an original or a reticle) 10. The pattern of the mask 10 is projected and transferred onto the wafer 217 via the projection system 101.

In step S12 of FIG. 3, the wafer detector 106 and wafer driver 107 adjust the orientation of the wafer 217 so that the direction which requires high-precision wafer alignment coincides with the measurement direction of the high-precision wafer alignment measurement system 102 on the substrate. A mask driver 108 rotates the orientation of the mask 10 in accordance with the adjusted orientation of the wafer 217 in step S12, and loads the mask 10 onto a mask stage in step S13. After the orientations of the wafer 217 and mask 10 are adjusted in this way, wafer alignment measurement processes as in the first embodiment are performed, the pattern on the wafer 217 and the pattern on the mask 10 are overlaid on each other, and then the wafer 217 is exposed.

[Method of Manufacturing Article]

A method of manufacturing an article according to an embodiment of the present invention is suitable for manufacturing various articles including a semiconductor device and an original (it can also be called, for example, a reticle or a mask). This manufacturing method can include a step of forming a pattern on a substrate, coated with a photosensitive agent, using the above-mentioned lithography apparatus, and a step of processing (for example, developing) the substrate having the pattern formed on it in the forming step. In manufacturing a device, this manufacturing method can also include subsequent known steps (for example, oxidation, film formation, vapor deposition, doping, planarization, etching, resist removal, dicing, bonding, and packaging).

Although embodiments of the present invention have been described above, the present invention is not limited to these embodiments, and various modifications or changes can be made without departing from the scope of this invention. The following modification or change, for example, is possible. The lithography apparatus is not limited to the above-mentioned examples. The lithography apparatus may be, for example, an imprint apparatus which molds an imprint agent (for example, a resin) on a substrate using a mold to form a pattern on the substrate (transfer a pattern onto the substrate). Note that in a method of manufacturing an article using an imprint apparatus, the above-mentioned processing step can be a step of removing a residual layer or another known processing step.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-011558 filed Jan. 23, 2012, which is hereby incorporated by reference herein in its entirety.

What is claimed is:

1. A lithography apparatus comprising:
a rotation mechanism configured to rotate a substrate;
a first measurement device configured to measure a position of an alignment mark formed on the substrate in a first direction with a first precision;
a second measurement device configured to measure a position of an alignment mark formed on the substrate in a second direction with a second precision higher than the first precision; and
a controller configured to control the rotation mechanism so that a direction, in which the substrate requires an overlay precision higher than another direction, is aligned with the second direction.

2. The apparatus according to claim 1, further comprising:
a substrate stage configured to hold the substrate,
wherein the rotation mechanism is configured to rotate the substrate before the substrate is held on the substrate stage.

3. The apparatus according to claim 1, further comprising:
a substrate stage configured to hold the substrate,
wherein the rotation mechanism is configured to rotate the substrate stage.

4. The apparatus according to claim 1, wherein
the lithography apparatus is configured to perform drawing on the substrate with a charged particle beam, and
the controller is configured to change data used for the drawing in accordance with rotation of the substrate by the rotation mechanism.

5. The apparatus according to claim 1, wherein
the lithography apparatus is configured to project a pattern formed on a mask onto the substrate to expose the substrate, and
the controller is configured to rotate the mask in accordance with rotation of the substrate by the rotation mechanism.

6. A method of manufacturing an article, the method comprising:
forming a pattern on a substrate using a lithography apparatus; and
processing the substrate on which the pattern has been formed to manufacture the article,
the lithography apparatus including:
a rotation mechanism configured to rotate the substrate;
a first measurement device configured to measure a position of an alignment mark formed on the substrate in a first direction with a first precision;
a second measurement device configured to measure a position of an alignment mark formed on the substrate in a second direction with a second precision higher than the first precision; and
a controller configured to control the rotation mechanism so that a direction, in which the substrate requires an overlay precision higher than another direction, is aligned with the second direction.
